(19) United States
(12) Patent Application Publication
(10) Pub. No.: US 2007/0114006 A1
(43) Pub. Date: May 24, 2007

(54) HEAT-DISSIPATING FIN ASSEMBLY FOR HEAT SINK

(76) Inventors: Chun-Chi Chen, Shenzhen (CN); Shih-Hsun Wung, Shenzhen (CN); Guang Yu, Shenzhen (CN); Da-Yuan Zhou, Shenzhen (CN); Jin-Biao Liu, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,366

(22) Filed: Nov. 21, 2005

(51) Int. Cl. H05K 7/20

(52) U.S. Cl. 165/78; 165/80.3; 361/704; 165/185

(57) ABSTRACT

A heat-dissipating fin assembly (1) includes a plurality of individual fin plates (10) arranged side by side. Each of the fin plates includes a main body (14) and a pair of flanges extending perpendicularly from opposite top and bottom sides of the main body. Each flange comprises a first plane extending from the main body and a second plane extending from the first plane. The second plane comprises a pair of engaging projections extending from two ends thereof. The second plane of a rear fin plate covers the first plane of an adjacent front fin plate. The rear and front fin plates are interlocked by the engaging projections of the rear fin plate bent to respectively engage two ends of the first plane of the front fin plate.

### FIELD OF THE INVENTION

The present invention generally relates to a heat sink for removing heat from electronic components and particularly to a heat sink comprising a plurality of interlocked fins.

### DESCRIPTION OF RELATED ART

With the continuing development of electronics technology, new electronic components can perform more and more functions. Heat generated by modern electronic components has increased considerably. Measures must be taken to efficiently remove the heat from the electronic components. Typically, a heat sink having great heat conductivity is mounted on the electronic component to remove heat therefrom.

A conventional heat sink includes a plurality of fins stacked together. Each of the fins comprises a main body and top and bottom flanges extending perpendicularly from respective top and bottom side edges of the body. Each of the top and bottom flanges defines a pair of locking slots near opposite ends thereof, and comprises a pair of insertion tabs adjacent the locking slots. Each insertion tab of the top flange forms a bulge on a bottom surface thereof, and defines a recess in an upper surface thereof. Each insertion tab of the bottom flange forms a bulge on an upper surface thereof, and defines a recess in a bottom surface thereof. In assembly, the insertion tabs of a rear one of the plates are inserted into the locking slots of an adjacent front one of the plates. The bulges of the insertion tabs of the rear plate are engaged in the recesses of the insertion tabs of the front plate, so that the rear plate is connected to the front plate. Other plates are then attached to the combined rear and front plates in sequence in the same way. The top flanges of the plates commonly define a top surface of the heat sink and the bottom flanges of the plates commonly define a bottom surface of the heat sink.

However, a seam exists between the flange of the rear plate and the main body of the front plate, perpendicular to the top and bottom surfaces of the heat sink. When solder paste is applied to the top or bottom surface of the heat sink, the liquid solder paste is prone to flow from one side of the flange to an opposite side of the flange and into the main body of the plate through the seam to form solder droplets on the main body. The solder droplets on the main bodies of the fin plates of the fin assembly affect not only the appearance but also the heat dissipation effectiveness of the heat sink.

### SUMMARY OF INVENTION

A heat-dissipating fin assembly comprises a plurality of individual fin plates arranged side by side. Each fin plate comprises a main body and a pair of flanges extending perpendicularly from opposite top and bottom sides of the main body. Each flange comprises a first plane extending from the main body and a second plane extending from and parallel to the first plane. The second plane comprises a pair of engaging projections extending from two ends thereof. The second plane of a rear one of the fin plates engagingly covers the first plane of an adjacent front one of the fin plates, and the rear and front fin plates are interlocked by the engaging projections of the second plane of the rear fin plate bent to respectively engage two ends of the first plane of the front fin plate.

Other advantages and novel features will become more apparent from the following detailed description of preferred embodiments when taken in conjunction with the accompanying drawings, in which:

### BRIEF DESCRIPTION OF DRAWING

FIG. 1 is an isometric view of a heat-dissipating fin assembly in accordance with a preferred embodiment of the present invention, the assembly comprising a plurality of fin plates;

FIG. 2 is a view similar to FIG. 1 with one fin plate separated from the others to more clearly show the structure of the fin plate;

FIG. 3 is an enlarged view of a circled part III of FIG. 2;

FIG. 4 is a side view of the separate fin plate of FIG. 2; and

FIG. 5 is an isometric view of a heat-dissipating fin assembly in accordance with another embodiment of the present invention.

### DETAILED DESCRIPTION

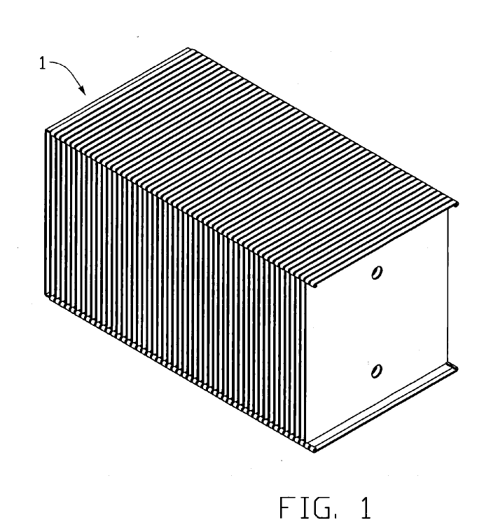

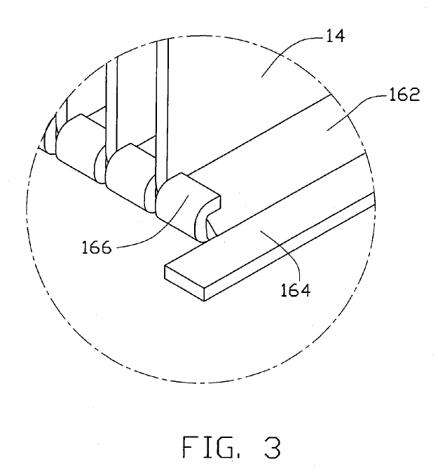

Referring to FIGS. 1-4, a heat-dissipating fin assembly 1 in accordance with a preferred embodiment of the present invention comprises a plurality of individual fin plates 10 arranged side by side.

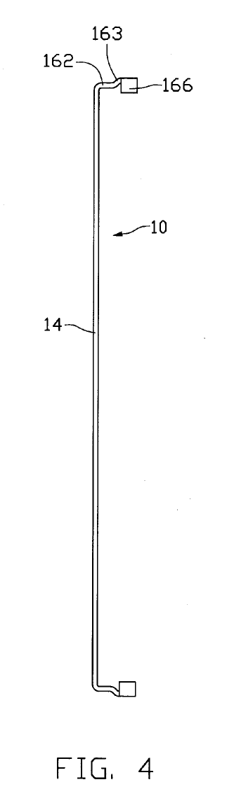

Each fin plate 10 is made of highly thermal conductive material such as aluminum or copper, and is formed by stamping to have a main body 14. A pair of flanges 16 extends perpendicularly from opposite top and bottom edges of the main body 14 respectively. Each flange 16 comprises a first plane 162 extending perpendicularly from each of the top and bottom edges of the main body 14 and a second plane 164 extending from a free edge of the first plane 162 and parallel to the first plane 162. The first plane 162 has a same breadth with the second plane 164, as viewed from a lateral side of the fin assembly 1. A pair of engaging projections 166 is formed at opposite ends of the second plane 164. The second plane 164 has a length larger than that of the first plane 162 as viewed from a front side of the fin assembly 1 before the engaging projections 166 are bent to engage with the first plane 162 of a neighboring front fin plate 10. A connecting portion 163 is formed between the first and second planes 162, 164 to connect the first and second planes 162, 164 together. Seeing FIG. 4, the connecting portion 163 is arc-shaped as viewed from the lateral side view of the fin plate 10. The connecting portion 163 extends outwardly from the first plane 162 toward the second plane 164 to make the first and second planes 162, 164 on different levels. The two planes 162, 164 are spaced from each other a distance substantially the same as a thickness of the fin plate 10 for forming the fin plate 10.

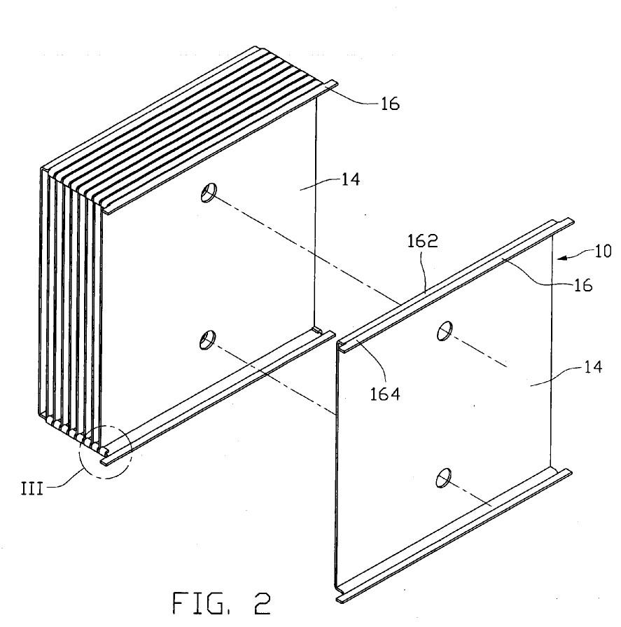

Referring to FIG. 2, in assembling the fin plates 10 to form the heat-dissipating fin assembly 1, the second plane 164 of a rear one of the fin plates 10 is engagingly received on an outer surface of the first plane 162 of an adjacent front one of the fin plates 10, so that the outer surface of the first plane 162 of the front fin plate 10 is covered by the second plane 164 of the rear fin plate 10. An Inner surface of the second plane 164 of the rear fin plate 10 is tightly attached on an outer surface of the first plane 162 of the front fin plate 10. All second planes 164 disposed on the first planes 162 are arranged at a same level to form flat top and bottom surfaces at top and bottom of the heat-dissipating fin assembly 1, respectively. The engaging projections 166 of the second plane 164 of the rear fin plate 10 are bent inwardly respectively from two ends of the second plane 164 to enclose and tightly engage two ends of the first plane 162 of the front fin plate 10, respectively. The engaging projections 166 of the rear fin plate 10 are used to avoid moving of the front fin plate 10 along a direction toward lateral sides of the fin assembly 1. All second planes 164 of the flanges 16 form a top and a bottom of the heat-dissipating fin assembly 1.

In the preferred embodiment of the present invention, a seam (not labeled) exists between a front edge of the second plane 164 of the rear fin plate 10 and an outer surface of the connecting portion 163 of the front fin plate 10. When solder paste is applied to the top or bottom of the heat-dissipating fin assembly 1, some of the liquid solder paste is received in the seams. Since the second planes 164 are tightly engaged with the first planes 162, the liquid solder plate is prevented to flow from the seams to the main bodies 14 of the fin plates 10 to form solder droplets thereon.

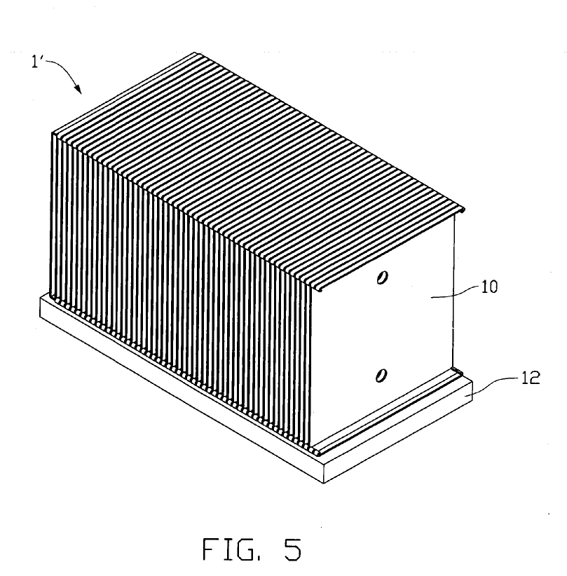

Referring to FIG. 5, in another embodiment of the present invention the heat-dissipating fin assembly 1′ comprises a base 12 and the flanges 16 of the bottom of the fin plates 10 are attached on the base 12.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat-dissipating fin assembly, comprising:
a plurality of individual fin plates arranged side by side and connected together, each of the fin plates comprising:
a main body; and
a pair of flanges extending perpendicularly from the main body, each flange comprising a first plane and a second plane extending from and parallel to the first plane, the second plane comprising a pair of engaging projections extending from two ends thereof;
wherein the second plane of a rear one of the fin plates engagingly covers the first plane of an adjacent front one of the fin plates and the rear and adjacent front fin plates are interlocked by the engaging projections of the rear fin plate respectively engaging with two ends of the first plane of the adjacent front fin plate.

2. The heat-dissipating fin assembly as claimed in claim 1, wherein each flange further comprises a connecting portion disposed between the first plane and the second plane to make the first and second planes located on different levels.

3. The heat-dissipating fin assembly as claimed in claim 1, wherein the first plane extends perpendicularly from a side of the main body and the second plane extends from free edge of the first plane.

4. The heat-dissipating fin assembly as claimed in claim 1, wherein the engaging projections extend inwardly from the two ends of the second plane of each flange.

5. The heat-dissipating fin assembly as claimed in claim 4, wherein the engaging projections of the second plane of the rear fin plate are bent to enclose the two ends of the first plane of the adjacent front fin plate to interlock the two fin plates together.

6. The heat-dissipating fin assembly as claimed in claim 4, wherein the flange comprises a connecting portion formed to connect the first and second planes together.

7. The heat-dissipating fin assembly as claimed in claim 6, wherein the connecting portion is arc-shaped.

8. The heat-dissipating fin assembly as claimed in claim 1, wherein the second plane of the rear fin plate tightly covers the first plane of the adjacent front plate.

9. The heat-dissipating fin assembly as claimed in claim 8, wherein the second plane has a breadth the same as that of the first plane.

10. The heat-dissipating fin assembly as claimed in claim 8, wherein all the second planes form flat top and bottom surfaces at top and bottom of the heat-dissipating fin assembly respectively.

11. A fin plate for a fin assembly for a heat dissipation device, comprising:
a rectangular main body having a bottom side, a top side opposite the bottom side and two opposite lateral sides connecting the top and bottom sides;
a flange extending from the bottom side of the main body, wherein the flange includes a first plane extending from the main body and a second plane extending from the first plane, the first and second planes being located at different levels with the second plane is located below the first plane.

12. The fin plate as claimed in claim 11, wherein the first plane and the second plane have the same breadth as viewed from the lateral side of the main body.

13. The fin plate as claimed in claim 11, wherein the second plane has a length which is longer than that of the first plane.

14. The fin plate as claimed in claim 11, wherein the flange comprises an arc-shaped connecting portion formed between the first and second planes to connect the first and second planes together.

15. The fin plate as claimed in claim 11, wherein the first and second planes are spaced from each other a distance which is substantially the same as a thickness of the fin plate.

16. The fin plate as claimed in claim 12, wherein the second plane has a length which is longer than that of the first plane.

17. The fin plate as claimed in claim 16, wherein the flange comprises an arc-shaped connecting portion formed between the first and second planes to connect the first and second planes together.

18. The fin plate as claimed in claim 17, wherein the first and the second planes are spaced from each other a distance with is substantially the same as a thickness of the fin plate.
